(19) United States
(12) Patent Application Publication
(10) Pub. No.: US 2026/0020455 A1
(43) Pub. Date: Jan. 15, 2026

(54) DISPLAY SUBSTRATE AND DISPLAY DEVICE

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Yanwei Lu, Beijing (CN); Fengli Ji, Beijing (CN)

(73) Assignees: CHENGDU BOE OPTOELECTRONICS TECHNOLOGY CO., LTD., Chengdu, Sichuan (CN); BOE TECHNOLOGY GROUP CO., LTD., Beijing (CN)

(21) Appl. No.: 18/994,841

(22) PCT Filed: Jan. 15, 2024
(86) PCT No.: PCT/CN2024/072260

§ 371 Date: Jan. 15, 2025

(30) Foreign Application Priority Data
Feb. 28, 2023 (CN) 202310212569.3

(51) Int. Cl. H10K 59/131; H10K 59/80

(52) U.S. Cl. CPC H10K 59/131; H10K 59/8722

(57) ABSTRACT

The present disclosure is directed to kappa opioid receptor ligands and pharmaceutical compositions thereof and their utility as neurological modulators (e.g., anti-nociceptive agents, antidepressants, anxiolytics, antipruritics). Specifically, the disclosed kappa opioid ligands are G-protein biased kappa opioid agonists containing a core and three different arms as is shown in Formula (A) below.

### CROSS-REFERENCE TO RELATED APPLICATION

The present application claims priority to the Chinese patent application No. 202310212569.3 filed in China on Feb. 28, 2023, a disclosure of which is incorporated herein by reference in its entirety.

### TECHNICAL FIELD

The present disclosure relates to the field of display technologies, in particular to a display substrate and display device.

### BACKGROUND

Organic light-emitting diode (Organic Light-Emitting Diode, OLED) display devices not only have the advantages of traditional liquid crystal displays (Liquid Crystal Display, LCD), but also have the advantages of self-light emitting, wide color gamut, high contrast, low power consumption, and thinness. Therefore, they are widely used in fields such as smartphones, wearable devices, notebooks, TVs, VR, etc. In order to better meet people's needs for various functions and provide a better screen experience, full screen borderless display has gradually become the mainstream form of OLED display devices. Therefore, the narrowing of borders is receiving increasing attention in the design and research of OLED display devices. Especially with the improvement of flexible active matrix OLED display technology, the terminal form is constantly changing, and folding, curling and other forms continue to appear, which has higher requirements for the narrowing of display screen borders. Therefore, the border size of flexible active matrix OLED display devices needs to be continuously optimized to meet the development trend of flexible products.

However, in available display products, there is a problem of poor brightness uniformity while meeting the narrow border requirements.

### SUMMARY

The purpose of the present disclosure is to provide a display substrate

and display device.

In order to achieve the above objectives, the present disclosure provides the following technical solutions:

The first aspect of the present disclosure provides a display substrate, including a substrate, the substrate includes a display area and a border area located around the display area, the border area includes a sealing area; the display substrate further includes:
a plurality of sub-pixels, located in the display area;
a plurality of power supply portions, located at least in the display area and electrically connected to the plurality of sub-pixels;
a first power line, including a first power portion, a second power portion, and a plurality of power connection portions, the first power portion is located between the second power portion and the display area, and at least a portion of the second power portion is located between the display area and the sealing area, the first power portion is coupled to the plurality of power supply portions, the plurality of power connection portions are located between the first power portion and the second power portion, and are coupled to both the first power portion and the second power portion;
a multiplexer circuit, wherein at least a portion of an orthographic projection of the multiplexer circuit on the substrate is located between an orthographic projection of the first power portion on the substrate and an orthographic projection of the second power portion on the substrate;
the multiplexer circuit includes a plurality of multiplexer units, the plurality of multiplexer units are alternately arranged with the plurality of power connection portions.

Optionally, the plurality of power connection portions include a first power connection portion and a plurality of second power connection portions, the plurality of second power connection portions include two sets of connection portion groups, an orthographic projection of the first power connection portion on the substrate is located between orthographic projections of the two sets of connection portion groups on the substrate;
a width of the first power connection portion in a direction perpendicular to its own extension direction is greater than a width of the second power connection portion in a direction perpendicular to its own extension direction.

Optionally, a width d3 of the second power portion in a direction perpendicular to its own extension direction satisfies: 15 μm≤d3≤25 μm.

Optionally, the display substrate includes a first gate metal layer, a second gate metal layer, a first source drain metal layer, and a second source drain metal layer stacked in sequence along a direction away from the substrate; the power connection portion is arranged on the same layer as at least one of the first gate metal layer, the second gate metal layer, the first source drain metal layer, or the second source drain metal layer.

Optionally, the first power line further includes at least one third power portion, the third power portion is coupled to the second power portion, and at least a portion of the third power portion is located in the sealing area;
the third power portion is arranged on the same layer as at least one of the first gate metal layer, the second gate metal layer, or the first source drain metal layer in the display substrate.

Optionally, the display substrate further includes a first signal input terminal; the first power line includes two third power portions, the two third power portions are symmetrically arranged; the first power line further includes two fourth power portions, and the fourth power portion is coupled to a corresponding third power portion and the first signal input terminal.

Optionally, the first power line further includes a fifth power portion and a sixth power portion, the fifth power portion is located between the two fourth power portions, and the fifth power portion is coupled to the two fourth power portions, at least a portion of the sixth power portion is located in the sealing area, and the sixth power portion is coupled to the fifth power portion and the second power portion.

Optionally, the display substrate further includes a first signal input terminal; the first power line includes a sixth power portion and a seventh power portion, the sixth power portion is coupled to the second power portion, and the seventh power portion includes a first portion and two second portions, the first portion extends along a first direction, and the first portion is coupled to the sixth power portion and the two second portions, the second portion extends along a second direction, and the second portion is coupled to the first signal input terminal, the first direction intersects with the second direction.

Optionally, the display substrate further includes:
a second power line, including an eighth power portion and two ninth power portions, the eighth power portion is arranged around the display area, and the two ninth power portions are coupled to two terminals of the eighth power portion in a one-to-one correspondence;
a second signal input terminal, coupled to the ninth power portion.

Optionally, the display substrate includes a first gate metal layer, a second gate metal layer, a first source drain metal layer, and a second source drain metal layer stacked in sequence along a direction away from the substrate;
at least a portion of the ninth power portion is located in the sealing area, and the ninth power portion is arranged on the same layer as the first source drain metal layer in the display substrate.

Optionally, the display substrate includes a first gate metal layer, a second gate metal layer, a first source drain metal layer, and a second source drain metal layer stacked in sequence along a direction away from the substrate;
at least a portion of the eighth power portion is located in the sealing area, and at least a portion of the eighth power portion is arranged on the same layer as the first gate metal layer in the display substrate.

Optionally, the display substrate further includes a fan-out line, at least a portion of an orthographic projection of the fan-out line on the substrate is located between an orthographic projection of the eighth power portion on the substrate and the display area.

Optionally, the display substrate includes a first gate metal layer, a second gate metal layer, a first source drain metal layer, and a second source drain metal layer stacked in sequence along a direction away from the substrate;
the ninth power portion includes a third portion and a fourth portion coupled to each other, at least a portion of the third portion is located in the sealing area, and the fourth portion is located in an area outside the sealing area, the third portion is arranged on the same layer as the first gate metal layer in the display substrate, the third portion and the eighth power portion are integrated structures, and the fourth portion is arranged on the same layer as the first source drain metal layer in the display substrate.

Optionally, the display substrate further includes a fan-out line; the eighth power portion includes a fifth portion and a sixth portion, an orthographic projection of the fifth portion on the substrate is located between an orthographic projection of the sixth portion on the substrate and the display area; the fifth portion and the sixth portion are respectively coupled to the ninth power portion;
at least a portion of an orthographic projection of the fan-out line on the substrate is located between the orthographic projection of the fifth portion on the substrate and the orthographic projection of the sixth portion on the substrate.

Optionally, the display substrate further includes a plurality of fan-out lines, at least some of the plurality of fan-out lines include a fan-out compensation portion, and at least a portion of the fan-out compensation portion located in the sealing area.

Optionally, the display substrate further includes a sealing compensation portion, the sealing compensation portion is located in the sealing area, in the sealing area, a layout density of the sealing compensation portion is the same as a layout density of the fan-out line.

Optionally, the display substrate further includes a plurality of fan-out lines, at least some of the plurality of fan-out lines include a fan-out compensation portion, the length of the fan-out compensation portions included in each fan-out line is approximately the same, and the fan-out compensation portions are uniformly arranged in the sealing area.

The second aspect of the present disclosure provides a display substrate, including a substrate, the substrate includes a display area and a border area located around the display area, the border area includes a sealing area; the display substrate further includes:
a plurality of sub-pixels, located in the display area;
a plurality of power supply portions, located at least in the display area and electrically connected to the plurality of sub-pixels;
a first power line, including a first power portion, a second power portion, and a plurality of power connection portions, the first power portion is located between the second power portion and the display area, and at least a portion of the second power portion is located between the display area and the sealing area, the first power portion is coupled to the plurality of power supply portions, the plurality of power connection portions are located between the first power portion and the second power portion, and are coupled to both the first power portion and the second power portion; the first power line further includes two third power portions and a sixth power portion, both of the third power portion and the sixth power portion are coupled to the second power portion, an orthographic projection of the sixth power portion on the substrate is located between orthographic projections of two third power portions on the substrate;
a plurality of fan-out lines, at least some of the plurality of fan-out lines include a fan-out portion extending along a second direction, at least a portion of an orthographic projection of the fan-out portion on the substrate, is located between an orthographic projection of the third power portion on the substrate and the orthographic projection of the sixth power portion on the substrate.

Optionally, the display substrate further includes a multiplexer circuit, at least a portion of an orthographic projection of the multiplexer circuit on the substrate is located within an area enclosed by the first power portion, the second power portion, and the plurality of power connection portions.

Based on the above technical solutions of the display substrate, the third aspect of the present disclosure provides a display device including the above display substrate.

### BRIEF DESCRIPTION OF THE DRAWINGS

The accompanying drawings described herein are intended to provide further understanding of the present disclosure and form a part of the present disclosure. The illustrative embodiments and their descriptions of the present disclosure are used to explain the present disclosure and do not constitute undue limitations on the present disclosure. In the accompanying drawings:

FIG. 1 is a schematic diagram of a structure of a display substrate provided in the embodiment of the present disclosure;

FIG. 2 is an enlarged schematic diagram of A1 section in FIG. 1;

FIG. 3 is a layout schematic diagram of a first power line and a multiplexer circuit in FIG. 1;

FIG. 4 is a first layout schematic diagram of the first power line and a second power line at the bottom left border of the display substrate provided in the embodiment of the present disclosure;

FIG. 5 is a second layout schematic diagram of the first power line and a multiplexer at the bottom border of the display substrate provided in the embodiment of the present disclosure;

FIG. 6 is a second layout schematic diagram of the first power line and the second power line at the bottom left border of the display substrate provided in the embodiment of the present disclosure;

FIG. 7 is a layout schematic diagram of the first power line and the second power line at the bottom right border of the display substrate provided in the embodiment of the present disclosure;

FIG. 8 is a layout schematic diagram of the second power line and the multiplexer circuit at the bottom left border of the display substrate provided in the embodiment of the present disclosure;

FIG. 9 is a third layout schematic diagram of the first power line and the multiplexer at the bottom border of the display substrate provided in the embodiment of the present disclosure;

FIG. 10 is a third layout schematic diagram of the first power line and the second power line at the bottom left border of the display substrate provided in the embodiment of the present disclosure;

FIG. 11 is an enlarged schematic diagram of A2 section in FIG. 1;

FIG. 12 is an enlarged schematic diagram of A3 section in FIG. 1;

FIG. 13 is a layout schematic diagram of the multiplexer circuit provided in the embodiment of the present disclosure;

FIG. 14 is a first layout schematic diagram of a fan-out line provided in the embodiment of the present disclosure;

FIG. 15 is a second layout schematic diagram of the fan-out line provided in the embodiment of the present disclosure;

FIG. 16 is a third layout schematic diagram of the fan-out line provided in the embodiment of the present disclosure;

FIG. 17 is a layout schematic diagram of the second power line and sub-pixels provided in the embodiment of the present disclosure;

FIG. 18 is a schematic cross-sectional view of the film layers along the B1B2 direction in FIG. 17;

FIG. 19 is a fourth layout schematic diagram of the first power line and the multiplexer at the bottom border of the display substrate provided in the embodiment of the present disclosure;

FIG. 20 is a fifth layout schematic diagram of the first power line and the multiplexer at the bottom border of the display substrate provided in the embodiment of the present disclosure; and

FIG. 21 is a schematic cross-sectional view of the film layers along the C1C2 direction in FIG. 20.

### DETAILED DESCRIPTION

In order to further illustrate the display substrate and display device provided in embodiments of the present disclosure, a detailed description will be provided below in conjunction with the accompanying drawings of the description.

Based on the technical problems existing in the background technology, it has been found through research that due to an attenuation of an input voltage of a power line connected to each row of sub-pixels in a display area of a display panel, brightness of the display panel varies at different positions. Therefore, in order to improve launch range uniformity (Launch Range Uniformity, LRU) of the display panel, it is necessary to minimize the voltage difference between the power lines connected to each row or column of sub-pixels as much as possible, so as to improve the launch range uniformity at different positions of the display area. Moreover, in order to ensure LRU, a power cord in conventional designs is often wide, occupying a large amount of space in a bottom border, making it more difficult to narrow the borders.

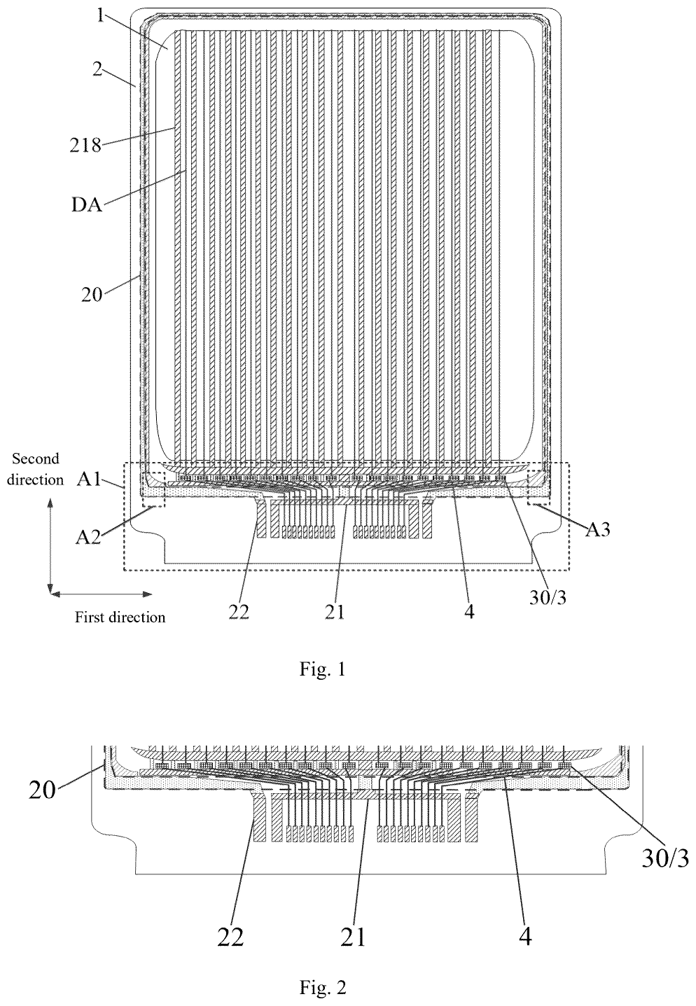

Please refer to FIGS. 1 to 3. The embodiment of the present disclosure provides a display substrate, including a substrate. The substrate includes a display area 1 and a border area 2 located around the display area 1. The border area 2 includes a sealing area 20; The display substrate further includes:
a plurality of sub-pixels, located in the display area 1;
a plurality of power supply portions 218, located at least in the display area 1 and electrically connected to the plurality of sub-pixels;
a first power line 21, including a first power portion 211, a second power portion 212, and a plurality of power connection portions 210. The first power portion 211 is located between the second power portion 212 and the display area 1, and at least a portion of the second power portion 212 is located between the display area 1 and the sealing area 20. The first power portion 211 is coupled to the plurality of power supply portions 218, and the plurality of power connection portions 210 are located between the first power portion 211 and the second power portion 212, and are coupled to both the first power portion 211 and the second power portion 212;
a multiplexer circuit 3, wherein at least a part of an orthographic projection of the multiplexer circuit 3 on the substrate is located between an orthographic projection of the first power portion 211 on the substrate and an orthographic projection of the second power portion 212 on the substrate; p1

the multiplexer circuit 3 includes a plurality of multiplexer units 30, the plurality of multiplexer units 30 are alternately arranged with the plurality of power connection portions 210.

Exemplarily, an orthographic projection of the plurality of power connection portions 210 on the substrate is located between the orthogonal projection of the first power portion 211 on the substrate and the orthogonal projection of the second power portion 212 on the substrate.

Exemplarily, the display area 1 includes a plurality of sub-pixels, and a plurality of sub-pixel driving circuits included in the plurality of sub-pixels are distributed in an array. The plurality of sub-pixel driving circuits are divided into a plurality of sub-pixel driving circuit rows and a plurality of sub-pixel driving circuit columns. The plurality of sub-pixel driving circuit rows are arranged along a second direction, and each row of the plurality of sub-pixel driving circuit rows includes a plurality of sub-pixel driving circuits arranged along a first direction. The plurality of sub-pixel driving circuit columns are arranged along the first direction, and each column of the plurality of sub-pixel driving circuit columns includes a plurality of sub-pixel driving circuits arranged along the second direction. Exemplarily, the first direction intersects with the second direction. For example, the first direction includes a transverse direction, and the second direction includes a longitudinal direction.

Exemplarily, the sub-pixel includes the sub-pixel driving circuit and a light-emitting element. The sub-pixel driving circuit is coupled to an anode of the light-emitting element to provide a driving signal for the light-emitting element and drive the light-emitting element to emit light.

Exemplarily, the first power line 21 further includes a plurality of power supply portions 218. At least a portion of the power supply portion 218 is located in the display area 1, and the power supply portion 218 is coupled to each sub-pixel driving circuit in a corresponding sub-pixel driving circuit column. For example, the first power line 21 is used to transmit positive power signals, but is not limited to this.

Exemplarily, the plurality of power supply portions are arranged along the first direction, and each power supply portion includes at least a portion extending along the second direction. The first power portion 211 is coupled to the plurality of power supply portions.

Exemplarily, the border area 2 includes a top border area, a bottom border area, a left border area, and a right border area. The first power portion 211, the second power portion 212, and the plurality of power connection portions 210 are located in the bottom border area, but are not limited to these.

Exemplarily, the border area 2 includes a sealing area 20. The sealing area 20 surrounds the display area 1 and is used to form a sealing adhesive.

Exemplarily, the first power line 21 includes a positive power signal line for transmitting positive power signals.

Exemplarily, the first power portion 211 includes at least a portion extending along the first direction, and the second power portion 212 includes at least a portion extending along the first direction. The power connection portion 210 includes at least a portion extending along the second direction, and the plurality of power connection portions 210 are spaced apart along the first direction. For example, the first power portion 211 and the second power portion 212 are arranged on the same layer as a first source drain metal layer in the display substrate.

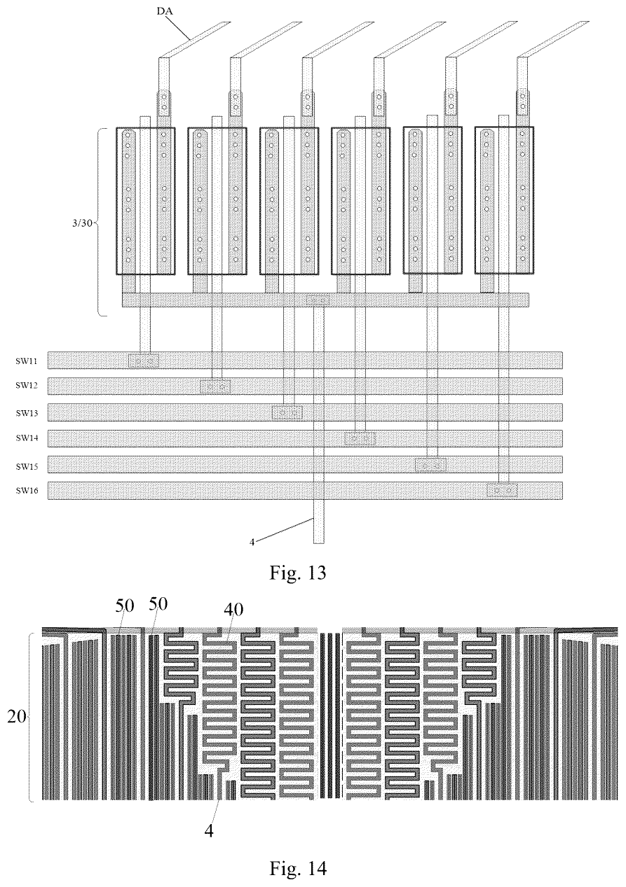

As shown in FIG. 13, a layout structure of the multiplexer is shown, where SW11 to SW16 are a plurality of switch control signal lines.

Exemplarily, the multiplexer circuit 3 includes a plurality of multiplexer units 30, each of which may have the same or different number of transistors, arranged along the first direction.

Exemplarily, the multiplexer unit 30 is alternately arranged with the power connection portion 210. For example, the power connection portion 210 passes through a layout area of the multiplexer circuit 3 to achieve coupling with the first power portion 211 and the second power portion 212.

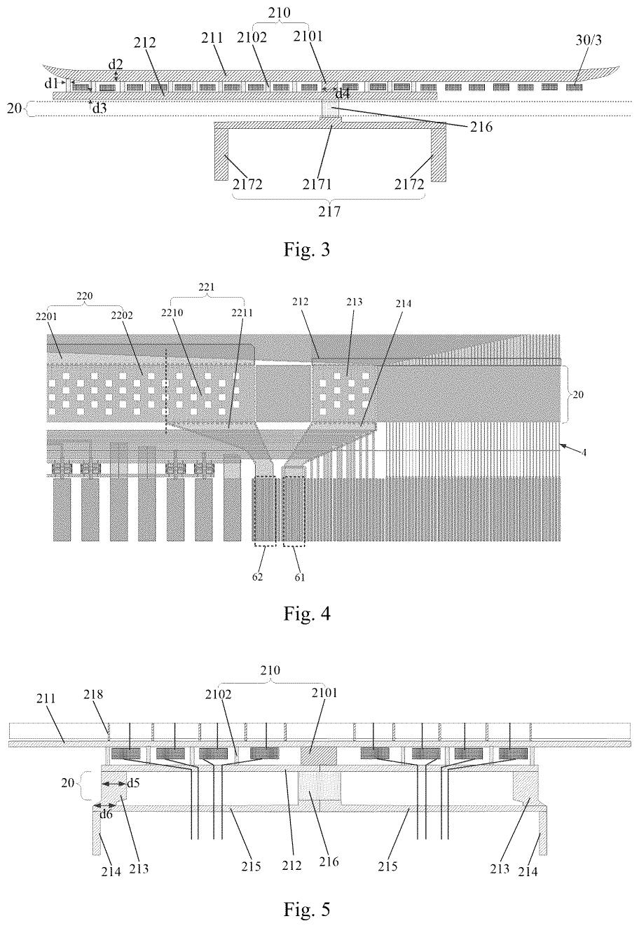

As shown in FIG. 3, exemplarily, at least a portion of the power connection portion 210 has a width d1 perpendicular to its own extension direction, which is smaller than a width d2 of the first power portion 211 in a direction perpendicular to its own extension direction.

As shown in FIG. 3, exemplarily, at least a portion of the power connection portion 210 has a width dl perpendicular to its own extension direction, which is smaller than a width d3 of the second power portion 211 in a direction perpendicular to its own extension direction.

According to the specific structure of the display substrate described above, it can be seen that in the display substrate provided in the embodiment of the present disclosure, the first power line 21 includes the first power portion 211, the second power portion 212, and a plurality of power connection portions 210, and the multiplexer unit 30 is alternately arranged with the power connection portion 210, so that the first power line 21 is formed into a mesh structure that can be inserted between the multiplexer circuits 3, and the first power line 21 can be divided into multiple channels and introduced into the display area 1. On the one hand, the above setting method can reduce the line width of the first power portion 211, the second power portion 212, and the power connection portion 210, reduce the space occupied by the first power line 21, and enable the display substrate to achieve better narrowing of borders; on the other hand, the introduction of multiple channels in the mesh structure can effectively improve the uniformity of the power signal transmitted by the first power line 21, enhance LRU, and improve the uniformity of the display brightness of the display substrate.

As shown in FIG. 3, in some embodiments, the plurality of power connection portions 210 include a first power connection portion 2101 and a plurality of second power connection portions 2102. The plurality of second power connection portions 2102 include two sets of connection portion groups. An orthographic projection of the first power connection portion 2101 on the substrate is located between orthographic projections of the two sets of connection portion groups on the substrate; A width d4 of the first power connection portion 2101 in a direction perpendicular to its own extension direction is greater than the width dl of the second power connection portion 2102 in the direction perpendicular to its own extension direction.

Exemplarily, the number of second power connection portions 2102 included in the two sets of connection portion groups is the same or different.

Exemplarily, the first power connection portion 2101 is arranged on the same layer as the first source drain metal layer in the display substrate, but not limited to this.

Exemplarily, the first power connection portion 2101 and the second power connection portion 2102 are arranged on different layers, but not limited to this.

Exemplarily, the number of multiplexer units 30 located on both sides of the first power connection portion 2101 is the same.

Exemplarily, the multiplexer units 30 located on both sides of the first power connection portion 2101 are symmetrically arranged.

Exemplarily, the number of second power connection portions 2102 located on both sides of the first power connection portion 2101 is the same.

Exemplarily, the second power connection portion 2102 located on both sides of the first power connection portion 2101 is symmetrically arranged.

In the display substrate provided by the above embodiments, by setting the width of the first power connection portion 2101 in the direction perpendicular to its own extension direction to be greater than the width of the second power connection portion 2102 in the direction perpendicular to its own extension direction, not only can the second power connection portion 2102 pass through the layout area of the multiplexer circuit 3 without short circuiting with the multiplexer circuit 3, but also the power signal transmitted by the first power line 21 can be transmitted to the first power portion 211 through the wider first power connection portion 2101, which is more conducive to the writing of power signals and the uniformity of display brightness of the display substrate.

As shown in FIG. 3, in some embodiments, the width d3 of the second power portion 212 in the direction perpendicular to its own extension direction satisfies: 15 μm≤d3≤25 μm.

Exemplarily, the width d3 of the second power portion 212 in the direction perpendicular to its own extension direction includes 15 μm, 18 μm, 20 μm, 22 μm, and 25 μm, but is not limited to these.

Setting the width of the second power portion 212 within the above range not only ensures the transmission capability of power signals, but also facilitates the narrowing of borders of the display substrate.

In some embodiments, the display substrate includes a first gate metal layer, a second gate metal layer, a first source drain metal layer, and a second source drain metal layer stacked in sequence along a direction away from the substrate; The power connection portion 210 is arranged on the same layer as at least one of the first gate metal layer, the second gate metal layer, the first source drain metal layer, or the second source drain metal layer.

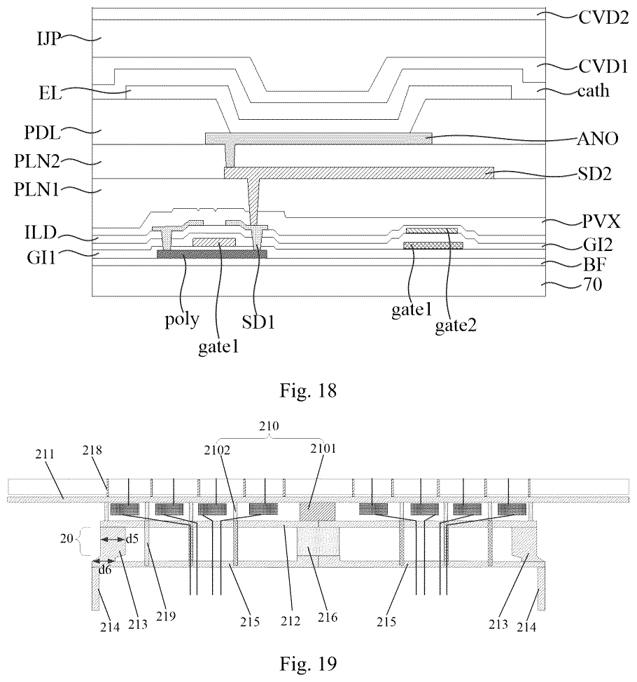

As shown in FIG. 18, exemplarily, the display substrate includes a buffer layer BF, an active layer poly, a first gate insulating layer GI1, a first gate metal layer gate1, a second gate insulating layer GI2, a second gate metal layer gate2, an interlayer insulating layer ILD, a first source drain metal layer SD1, a first flat layer PLN1, a second source drain metal layer SD2, a second flat layer PLN2, an anode layer ANO, a light-emitting functional layer EL, a cathode layer cath, a first inorganic encapsulation layer CVD1, an organic encapsulation layer IJP, and a second inorganic encapsulation layer CVD2, which are sequentially stacked in a direction away from the substrate 70. The display substrate may further include a passivation layer PVX, but is not limited to this.

In the display substrate provided in the above embodiments, the power connection portion 210 is arranged on the same layer as at least one of the first gate metal layer, the second gate metal layer, the first source drain metal layer, and the second source drain metal layer, so that the power connection portion 210 can be formed simultaneously with other film layers in the display substrate in the same patterning process, avoiding a need for additional patterning processes to form the power connection portion 210, effectively simplifying the manufacturing process of the display substrate, and reducing the manufacturing cost of the display substrate.

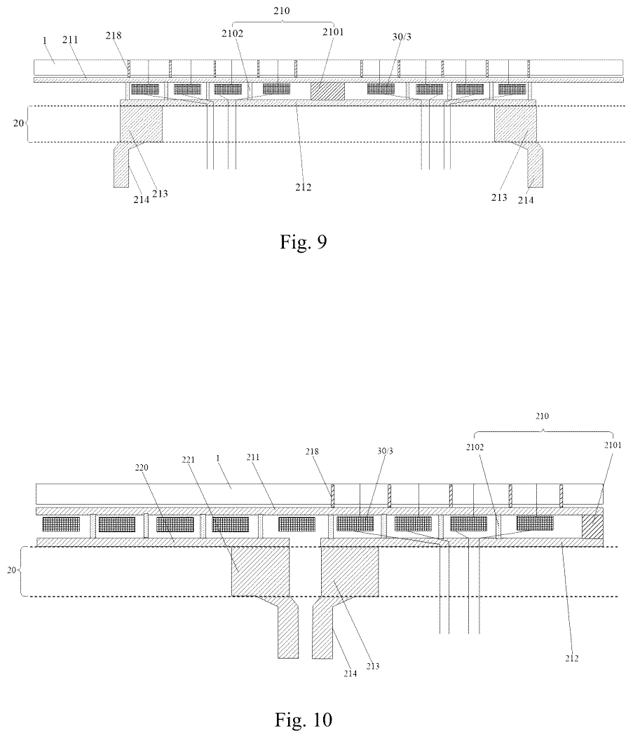

As shown in FIGS. 3, 4, 5, 6, 7, 9, and 10, in some embodiments, the first power line 21 further includes at least one third power portion 213, which is coupled to the second power portion 212, and at least a portion of the third power portion 213 is located in the sealing area 20;

The third power portion 213 is arranged on the same layer as at least one of the first gate metal layer, the second gate metal layer, and the first source drain metal layer in the display substrate.

Exemplarily, the third power portion 213 and the second power portion 212 are formed as an integrated structure, and both the third power portion 213 and the second power portion 212 are arranged on the same layer as the first source drain metal layer.

Exemplarily, the third power portion 213 is arranged on the same layer as the first gate metal layer or the second gate metal layer, and the second power portion 212 is arranged on the same layer as the first source drain metal layer.

Exemplarily, the third power portion 213 is located in the sealing area 20, and is arranged on the same layer as the first source drain metal layer. The third power portion 213 located in the sealing area 20 is reused as a sealing base of the sealing area 20, in contact with the sealing adhesive. Except for the area where the third power portion 213 is located, the structure of other areas in the sealing area 20 is made of the first gate metal layer and/or the second gate metal layer.

Exemplarily, the third power portion 213 is located in the sealing area 20, and is arranged on the same layer as the first gate metal layer. The third power portion 213 located in the sealing area 20 is reused as the sealing base of the sealing area 20, in contact with the sealing adhesive. The portion of the display substrate located in the sealing area 20 is arranged on the same layer as at least one of the first gate metal layer and the second gate metal layer in the display substrate.

In the display substrate provided in the above embodiments, the third power portion 213 is arranged on the same layer as the first gate metal layer and/or the second gate metal layer, which can reduce the segment differences generated by the third power portion 213 in the sealing area 20 and improve the sealing reliability of the sealing adhesive.

In the display substrate provided in the above embodiments, the third power portion 213 is arranged on the same layer as the first source drain metal layer or the second source drain metal layer, and other structures in the sealing area 20 are made of the first gate metal layer or the second gate metal layer, which can greatly reduce the proportion of the first source drain metal layer in the sealing area 20, reduce the segment differences caused by the first source drain metal layer in the sealing area 20, improve the sealing reliability of the sealing adhesive, and significantly improve the overall drop problem of the machine.

As shown in FIGS. 4, 5, 6, 7, 9, and 10, in some embodiments, the display substrate further includes a first signal input terminal 61; The first power line 21 includes two third power portions 213, which are symmetrically arranged; The first power line 21 further includes two fourth power portions 214, which are respectively coupled to the corresponding third power portion 213 and the first signal input terminal 61.

Exemplarily, two fourth power portions 214 are symmetrically arranged, and the fourth power portions 214 are coupled one-to-one with the third power portions 213.

Exemplarily, the fourth power portions 214 is located on the side of the sealing area 20 away from the display area 1.

Exemplarily, the fourth power portions 214 are arranged on the same layer as the first source drain metal layer.

Exemplarily, the third power portion 213 is provided with a hollow area, which can increase the adhesion between the sealing adhesive in the sealing area 20 and the sealing base.

As shown in FIG. 5, exemplarily, a width d5 of a portion of the third power portion 213 located in the sealing area 20 is greater than a width d6 of a portion of the third power portion 213 located in a non-sealing area 20.

As shown in FIGS. 5, 6, and 7, in some embodiments, the first power line 21 further includes a fifth power portion 215 and a sixth power portion 216. The fifth power portion 215 is located between the two fourth power portions 214, and the fifth power portion 215 is coupled to the two fourth power portions 214. At least a portion of the sixth power portion 216 is located in the sealing area 20, and the sixth power portion 216 is coupled to the fifth power portion 215 and the second power portion 212.

Exemplarily, the fifth power portion 215 and the fourth power portion 214 are formed as an integrated structure.

Exemplarily, the fifth power portion 215 is arranged on the same layer as the first source drain metal layer in the display substrate.

Exemplarily, the fifth power portion 215 is located on the side of the sealing area 20 away from the display area 1.

Exemplarily, the sixth power portion 216 is arranged on the same layer as the first gate metal layer in the display substrate.

In the display substrate provided in the above embodiments, the first power line 21 includes the fifth power portion 215 and the sixth power portion 216, so that the second power portion 212, the third power portion 213, the fourth power portion 214, the fifth power portion 215, and the sixth power portion 216 can form a mesh structure together. This arrangement further improves the brightness uniformity of the display substrate.

As shown in FIG. 19, in some embodiments, the first power line 21 further includes at least one compensation power portion 219, which is coupled to the second power portion 212 and the fifth power portion 215, respectively. At least a portion of the compensation power portion 219 is located in the sealing area 20.

Exemplarily, the compensation power portion 219 is set in the same layer and material as the first source drain metal layer.

Exemplarily, the compensation power portion 219 is set in the same layer and material as the second source drain metal layer.

Exemplarily, the compensation power portion 219 is formed as an integrated structure with the second power portion 212 and the fifth power portion 215.

The first power line 21 further includes at least one compensating power portion 219, which enhances the transmission performance of the first power line 21 and improves IR Drop of the first power line 21.

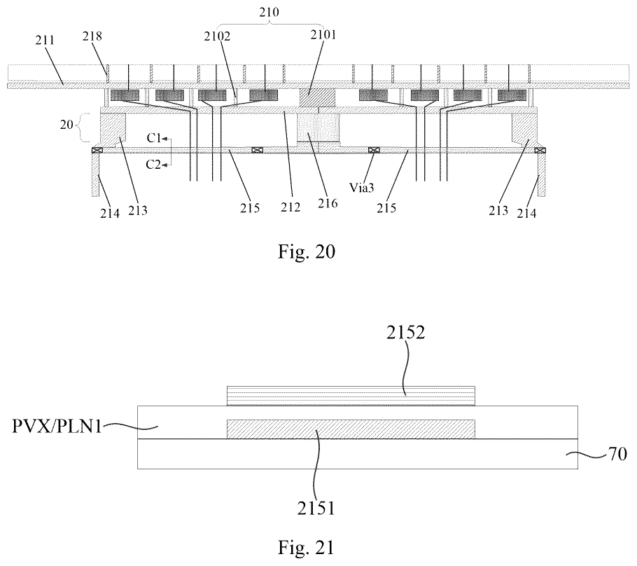

As shown in FIGS. 20 and 21, in some embodiments, the fifth power portion 215 includes a first sub portion 2151 and a second sub portion 2152 arranged in a stacked manner. An orthographic projection of the first sub portion 2151 on the substrate 70 overlaps with an orthographic projection of the second sub portion 2152 on the substrate 70, and in this overlapping area, the first sub portion 2151 and the second sub portion 2152 are coupled through at least one via hole Via3.

Exemplarily, the first sub portion 2151 is arranged on the same layer and material as the first source drain metal layer, and the second sub portion 2152 is arranged on the same layer and material as the second source drain metal layer.

The fifth power portion 215 includes a first sub portion 2151 and a second sub portion 2152 arranged in a stacked manner, which enhances the transmission performance of the first power line 21 and improves IR Drop of the first power line 21.

As shown in FIG. 3, in some embodiments, the display substrate further includes a first signal input terminal; The first power line 21 includes a sixth power portion 216 and a seventh power portion 217. The sixth power portion 216 is coupled to the second power portion 212, and the seventh power portion 217 includes a first portion 2171 and two second portions 2172. The first portion 2171 extends along the first direction, and the first portion 2171 is coupled to the sixth power portion 216 and the two second portions 2172, respectively. The second portion 2172 extends along the second direction, and the second portion 2172 is coupled to the first signal input terminal. The first direction intersects with the second direction.

Exemplarily, the sixth power portion 216 and the first power connection portion 2101 are arranged along the second direction.

Exemplarily, the sixth power portion 216 is arranged on the same layer as the first gate metal layer in the display substrate. The sixth power portion 216 is coupled to the second power portion 212 through a via hole, and the sixth power portion 216 is coupled to the seventh power portion 217 through a via hole.

Exemplarily, the first portion 2171 and the two second portions 2172 are formed as an integrated structure.

Exemplarily, the two terminals of the first portion 2171 are coupled one-to-one with the two second portions 2172, and the middle portion of the first portion 2171 is coupled with the sixth power portion 216.

Exemplarily, the seventh power portion 217 is located on the side of the sealing area 20 away from the display area 1.

Exemplarily, the seventh power portion 217 is arranged on the same layer as the first source drain metal layer in the display substrate.

In the display substrate provided in the above embodiments, the sixth power portion 216 is arranged on the same layer as the first and/or second gate metal layers, and other structures in the sealing area 20 are made of the first and/or second gate metal layers. This design allows only the first and/or second gate metal layers to be used in the structures located in the sealing area 20, avoiding the segment differences caused by the first source drain metal layer in the sealing area 20, improving the sealing reliability of the sealing adhesive, and significantly improving the overall drop problem of the machine.

As shown in FIGS. 1, 2, 4, 6, 7, 8, and 10, in some embodiments, the display substrate further includes:
a second power line 22, including an eighth power portion 220 and two ninth power portions 221. The eighth power portion 220 is arranged around the display area 1, and the two ninth power portions 221 are coupled to two terminals of the eighth power portion 220 in a one-to-one correspondence;
a second signal input terminal 62, coupled to the ninth power portion 221.

Exemplarily, the second power line 22 includes a negative power signal line, but is not limited to this. The second power line 22 is coupled to a cathode in the display substrate for providing a signal to the cathode.

Exemplarily, at least a portion of the eighth power portion 220 is arranged around the display area 1, and the two terminals of the eighth power portion 220 form openings on the bottom border of the display substrate. The two ninth power portions 221 are coupled one-to-one with the two terminals of the eighth power portion 220.

Exemplarily, the second signal input terminal 62 is used to provide a second power signal to the second power line 22.

Exemplarily, at least a portion of the ninth power portion 221 extends along the second direction.

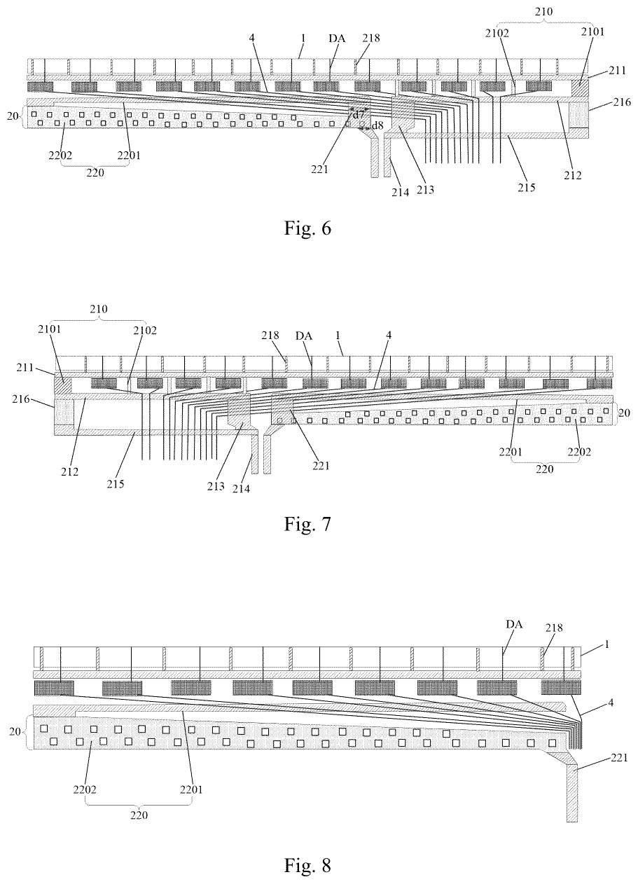

As shown in FIGS. 6, 7, and 10, in some embodiments, the display substrate includes a first gate metal layer, a second gate metal layer, a first source drain metal layer, and a second source drain metal layer stacked in sequence along a direction away from the substrate;

At least a portion of the ninth power portion 221 is located in the sealing area 20, and the ninth power portion 221 is arranged on the same layer as the first source drain metal layer in the display substrate.

Exemplarily, the display substrate includes two ninth power portions 221 symmetrically arranged, with the axis of symmetry located between the two ninth power portions 221.

Exemplarily, the ninth power portion 221 is provided with a hollow area, which can increase the adhesion between the sealing adhesive in the sealing area 20 and the sealing base.

Exemplarily, at least a portion of the ninth power portion 221 and the eighth power portion 220 are formed as an integrated structure.

As shown in FIG. 6, exemplarily, a width d7 of a portion of the ninth power portion 221 located in the sealing area 20 is greater than a width d8 of a portion of the ninth power portion 221 located in the non-sealing area 20.

Exemplarily, the ninth power portion 221 and the third power portion 213 included in the first power line 21 are both arranged on the same layer as the first source drain metal layer.

The ninth power portion 221 is arranged on the same layer as the first source drain metal layer, so that the ninth power portion 221 can be formed in the same patterning process as the first source drain metal layer, avoiding an introduction of additional patterning processes for the production of the ninth power portion 221, effectively simplifying the production process of the display substrate and reducing the production cost of the display substrate.

In the display substrate provided in the above embodiments, the ninth power portion 221 and the third power portion 213 included in the first power line 21 are both arranged on the same layer as the first source drain metal layer. Other structures in the sealing area 20 are made of the first gate metal layer or the second gate metal layer, which can greatly reduce the proportion of the first source drain metal layer in the sealing area 20, reduce the segment differences caused by the first source drain metal layer in the sealing area 20, thereby improving the sealing reliability of the sealing adhesive and significantly improving the overall drop problem of the machine.

As shown in FIG. 8, in some embodiments, the display substrate includes a first gate metal layer, a second gate metal layer, a first source drain metal layer, and a second source drain metal layer stacked in sequence along a direction away from the substrate;

At least a portion of the eighth power portion 220 is located in the sealing area 20, and at least a portion of the eighth power portion 220 (such as a sixth portion 2202) is arranged on the same layer as the first gate metal layer in the display substrate.

Exemplarily, a portion of the eighth power portion 220 located in the sealing area 20 is reused as a sealing base, in contact with the sealing adhesive.

The above setting method increases the area of the structure made of the first gate metal layer in the sealing area 20, reduces the segment differences caused by the first source drain metal layer in the sealing area 20, improves the sealing reliability of the sealing adhesive, and significantly improves the overall drop problem of the machine.

The eighth power portion 220 is arranged on the same layer as the first gate metal layer, so that the eighth power portion 220 can be formed in the same patterning process as the first gate metal layer, avoiding an introduction of additional patterning processes for the production of the eighth power portion 220, effectively simplifying the production process of the display substrate and reducing the production cost of the display substrate.

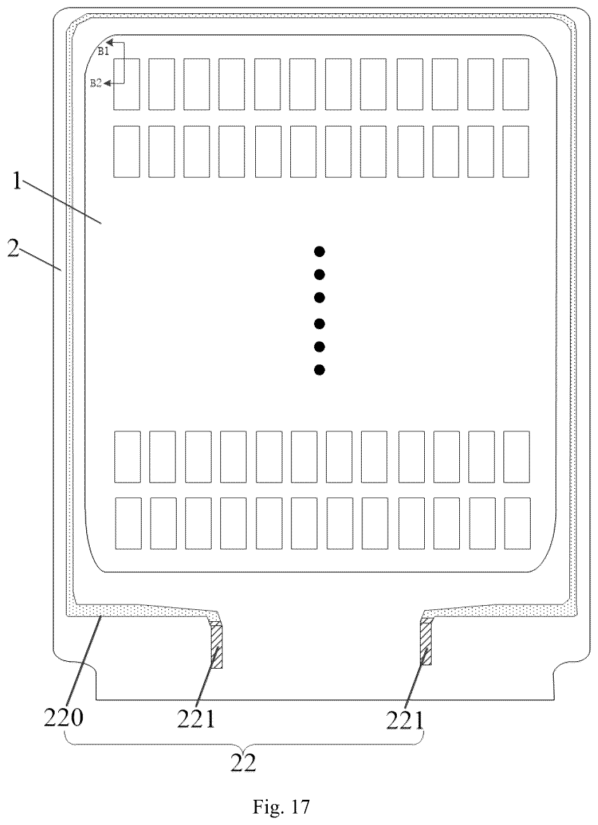

As shown in FIGS. 6, 7, and 17, in some embodiments, the display substrate further includes a fan-out line 4. At least a portion of an orthographic projection of the fan-out line 4 on the substrate is located between an orthographic projection of the eighth power portion 220 on the substrate and the display area 1.

As shown in FIG. 1, exemplarily, the display substrate further includes a plurality of data lines DA, at least a portion of which is located in the display area 1. The plurality of data lines DA are arranged along the first direction, and the data lines DA include at least a portion extending along the second direction. The data line DA is coupled to a corresponding fan-out line 4, which is coupled to a corresponding data signal input terminal. The data signals provided by the data signal input terminal are transmitted to the data line DA through the fan-out line 4.

In the display substrate provided in the above embodiments, the eighth power portion 220 extends around a portion of the fan-out line 4, from the bottom border of the display substrate to the corners of the left border and right border of the display substrate, connected to the first gate metal layer and interlayer insulation layer at the corners of the left border and right border, and then electrically connected to the first source drain metal layer that transmits the second power signal through a via hole.

As shown in FIG. 4, in some embodiments, the display substrate includes a first gate metal layer, a second gate metal layer, a first source drain metal layer, and a second source drain metal layer stacked in sequence along a direction away from the substrate;

The ninth power portion 221 includes a third portion 2210 and a fourth portion 2211 coupled to each other. At least a portion of the third portion 2210 is located in the sealing area 20, and the fourth portion 2211 is located in an area outside the sealing area 20. The third portion 2210 is arranged on the same layer as the first gate metal layer in the display substrate. The third portion 2210 and the eighth power portion 220 are integrated structures, and the fourth portion 2211 is arranged on the same layer as the first source drain metal layer in the display substrate.

Exemplarily, the third portion 2210 and the fourth portion 2211 are electrically connected through a via hole.

Exemplarily, the third portion 2210 includes a plurality of openings, and the source drain metal layer includes multiple groups of via holes, with each group of via holes including an array distribution of multiple via holes. An orthographic projection of each group of via holes on the substrate is located inside an orthographic projection of a corresponding opening on the substrate. The setting method can increase the bonding area between the sealing adhesive and the sealing base, and improve the adhesion between the sealing adhesive and the sealing base. It is worth noting that the third power portion 213 can also be provided with this structure of openings and multiple groups of via holes.

The third portion 2210 is arranged on the same layer as the first gate metal layer, which can reduce the segment differences generated by the first source drain metal layer in the sealing area 20, thereby better improving the sealing reliability of the sealing adhesive.

As shown in FIGS. 4, 6, 7, and 8, in some embodiments, the display substrate further includes a fan-out line 4; The eighth power portion 220 includes a fifth portion 2201 and a sixth portion 2202. An orthographic projection of the fifth portion 2201 on the substrate is located between an orthographic projection of the sixth portion 2202 on the substrate and the display area 1; The fifth portion 2201 and the sixth portion 2202 are respectively coupled to the ninth power portion 221;

At least a portion of the orthographic projection of the fan-out line 4 on the substrate is located between the orthographic projection of the fifth portion 2201 on the substrate and the orthographic projection of the sixth portion 2202 on the substrate.

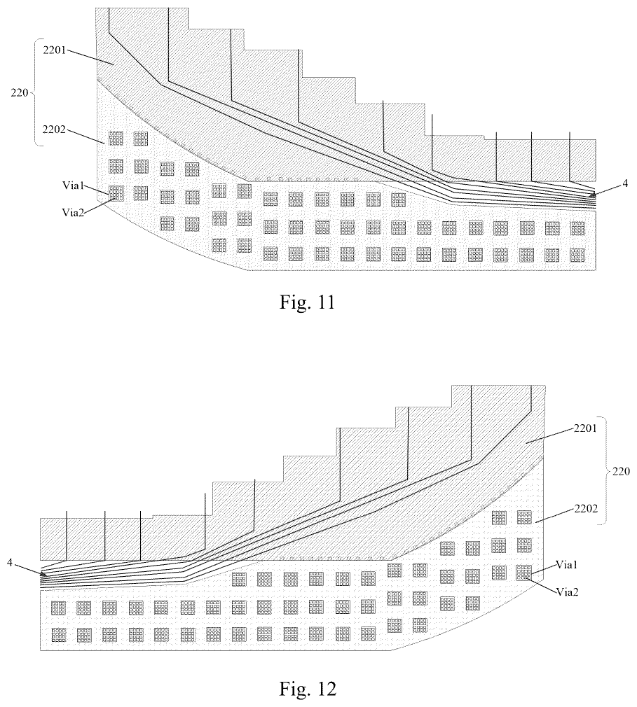

As shown in FIGS. 11 and 12, in the border areas at the bottom left and bottom right corners of the display substrate, the fifth portion 2201 is arranged on the same layer as the first source drain metal layer, and the sixth portion 2202 is arranged on the same layer as the first gate metal layer. The sixth portion 2202 includes a plurality of protrusions, and an orthographic projection of the protrusions on the substrate overlaps with the orthographic projection of the fifth portion 2201 on the substrate. The fifth portion 2201 and the sixth portion 2202 are coupled through a via hole in the overlapping area.

As shown in FIGS. 11 and 12, a first via hole Via1 is provided on the sixth portion, and a second via hole Via2 is formed on the subsequent interlayer insulation layer. A size of the second via hole Via2 is smaller than a size of the first via hole Via1. The second via hole Via2 is divided into multiple groups, and an orthographic projection of each group of Via2 on the substrate is located inside a corresponding orthographic projection of the first via Vial on the substrate.

Exemplarily, the fifth portion 2201 is arranged on the same layer as the first source drain metal layer in the display substrate, and the sixth portion 2202 is arranged on the same layer as the first gate metal layer in the display substrate. The fifth portion 2201 is formed as an integrated structure with the ninth power portion 221.

The above setting method enables the fifth portion 2201, the sixth portion 2202, and the ninth power portion 221 to form a mesh structure together. This mesh structure makes the second power signal transmitted by the second power line 22 more uniform, without any change points, which is more conducive to LRU.

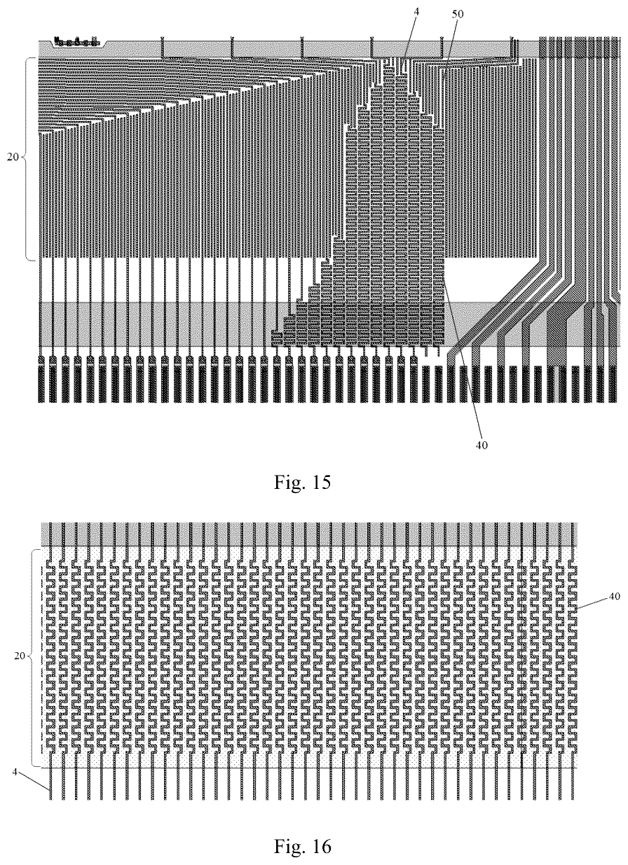

As shown in FIGS. 14 to 16, in some embodiments, the display substrate further includes a plurality of fan-out lines 4, at least some of which include a fan-out compensation portion 40, and at least a portion of the fan-out compensation portion 40 located in the sealing area 20.

Exemplarily, in order to ensure the uniformity of the load on each data line, a fan-out compensation portion 40 will be set for some fan-out lines 4. The fan-out compensation portion 40 may include folded bow shaped wiring, but is not limited to this.

Exemplarily, the length of the fan-out compensation portion 40 included in each fan-out line 4 is different, but not limited to this.

Exemplarily, all fan-out compensation portions 40 are set in the sealing area 20 and reused as the sealing base.

The fan-out compensation portion 40 is set in the sealing area 20, and the fan-out compensation portion 40 is reused as a sealing base, which can effectively increase the contact area between the sealing adhesive and the sealing base, improve the sealing ability, and achieve better water oxygen barrier and sealing effect.

As shown in FIGS. 14 and 15, in some embodiments, the display substrate further includes a sealing compensation portion 50, which is located in the sealing area 20. In the sealing area 20, the layout density of the sealing compensation portion 50 is the same as the layout density of the fan-out line 4.

Exemplarily, the sealing compensation portion 50 is arranged on the same layer as the first gate metal layer and/or the second gate metal layer in the display substrate.

Exemplarily, the sealing compensation portion 50 includes a strip-shaped graphic extending along the second direction. The sealing compensation portion is arranged in the sealing area 20, in an interval area between adjacent fan-out lines 4.

Exemplarily, the sealing compensation portion 50 is insulated from the fan-out line 4.

Exemplarily, the sealing compensation portion 50 is reused as the sealing base.

The above-mentioned setting of the sealing compensation portion 50 in the sealing area 20 can effectively increase the contact area between the sealing adhesive and the sealing base, improve the sealing ability, and achieve better water oxygen barrier and sealing effect.

As shown in FIG. 16, in some embodiments, the display substrate further includes a plurality of fan-out lines 4, at least some of which include a fan-out compensation portion 40. The length of the fan-out compensation portions 40 included in each fan-out line 4 is approximately the same, and the fan-out compensation portions 40 are uniformly arranged in the sealing area 20.

Exemplarily, the length of the fan out compensation portion 40 included in each fan out line 4 is the same or similar.

The above-mentioned setting of the sealing compensation portion 50 in the sealing area 20 can effectively increase the contact area between the sealing adhesive and the sealing base, improve the sealing ability, and achieve better water oxygen barrier and sealing effect.

In some embodiments, a portion of the display substrate located in the sealing area 20 is arranged on the same layer as at least one of the first gate metal layer and the second gate metal layer in the display substrate.

Exemplarily, in the display substrate, the portion located in the sealing region 20 as the sealing base is arranged on the same layer as at least one of the first gate metal layer and the second gate metal layer in the display substrate.

The above setting method can avoid the occurrence of segment differences caused by the first source drain metal layer in the sealing area 20, thereby better improving the adhesive reliability of the sealing adhesive and improving the overall falling NG of the machine.

As shown in FIGS. 5 and 6, the embodiment of the present disclosure further provides a display substrate, including a substrate, wherein the substrate includes a display area 1 and a border area 2 located around the display area 1. The border area 2 includes a sealing area 20; The display substrate further includes:
a plurality of sub-pixels, located in the display area 1;
a plurality of power supply portions 218, located at least in the display area 1 and electrically connected to the plurality of sub-pixels;
a first power line 21, including a first power portion 211, a second power portion 212, and a plurality of power connection portions 210. The first power portion 211 is located between the second power portion 212 and the display area 1, and at least a portion of the second power portion 212 is located between the display area 1 and the sealing area 20. The first power portion 211 is coupled to the plurality of power supply portions 218, and the plurality of power connection portions 210 are located between the first power portion 211 and the second power portion 212, and are coupled to both the first power portion 211 and the second power portion 212; The first power line further includes two third power portions 213 and a sixth power portion 216, both of which are coupled to the second power portion 212. An orthographic projection of the sixth power portion 216 on the substrate is located between orthographic projections of two third power portions 213 on the substrate;
a plurality of fan-out lines 4, at least some of which include a fan-out portion extending along the second direction. At least a portion of an orthographic projection of the fan-out portion on the substrate, is located between an orthographic projection of the third power portion 213 on the substrate and the orthographic projection of the sixth power portion 216 on the substrate.

The above setting method can concentrate the fan-out portion between the third power portion 213 and the sixth power portion 216, and then extend to the position where a driving chip is located and connect with the driving chip to receive corresponding signals. The method is conducive to reducing the difficulty of binding the driving chip and reducing the border width of the display substrate.

In some embodiments, a multiplexer circuit 3 is further included, wherein at least a portion of an orthographic projection of the multiplexer circuit 3 on the substrate is located within an area enclosed by the first power portion 211, the second power portion 212, and the plurality of power connection portions 210.

The above setting method can disperse the layout of the multiplexer circuit, enabling the display substrate to better achieve narrow border.

The embodiment of the present disclosure further provides a display device including the display substrate provided in the above embodiments.

It should be noted that the display device can be any product or component with display function, such as television, monitor, digital photo frame, mobile phone, tablet computer, etc. The display device also includes flexible circuit board, printed circuit board, and backplane. The display device can also be a flexible wearable OLED display product or a rigid wearable OLED display product.

In the display substrate provided by the above embodiments, the first power line includes the first power portion, the second power portion, and the plurality of power connection portions, and the multiplexer units are alternately arranged with the power connection portions, so that the first power line can become a mesh structure that can be inserted between the multiplexer circuits, and the first power line can be divided into multiple channels and introduced into the display area. On the one hand, the above setting method can reduce the line width of the first power portion, the second power portion, and the power connection portion, reduce the space occupied by the first power line, and enable the display substrate to achieve better narrowing of borders; on the other hand, the introduction of multiple channels in the mesh structure can effectively improve the uniformity of the power signal transmitted by the first power line, enhance LRU, and improve the uniformity of the display brightness of the display substrate.

The display device provided in the embodiment of the present disclosure also has the above-mentioned beneficial effects when including the display substrate, which will not be repeated here.

It should be noted that an extension of the signal line along the X direction refers to: the signal line includes a main portion and a secondary portion connected to the main portion, the main portion is a line, line segment or bar shaped body, the main portion extends along the X direction, and the length of the main portion extending along the X direction is greater than the length of the secondary portion extending in other directions.

It should be noted that “the same film layer” in an embodiment of the present disclosure may refer to a film layer located on the same structural layer. Alternatively, for example, the film layer at the same level may be a film layer formed to have a specific pattern by using the same film-forming process. The film layer may then be patterned by one patterning process using the same mask to form the desired layer structure. Depending on different specific patterns, the one patterning process may include multiple exposing, developing, or etching processes. Further, as an example, a specific pattern in the formed layer structure may be continuous or discontinuous. As other example, these specific patterns may be at different heights or have different thicknesses.

In the method embodiments of the invention, the sequential number of each step is not used to limit the order of the steps. Instead, the order of the steps may be changed by those skilled in the art without any inventive effort and is thus under the protection of the invention.

The various embodiments in the present description are described in a progressive manner, and the various embodiments may refer to each other for the same or similar portions, and each embodiment focuses on differences from other embodiments. Especially, for the method embodiment, since it is basically similar to the product embodiment, the description is relatively simple, and the relevant portions can be referred to the description of the product embodiment.

Unless otherwise defined, the technical terminology or scientific terminology used herein should have the same meaning as commonly understood by one of ordinary skill in the art to which this invention belongs. Likewise, terms like “first,” “second,” etc., which are used in the description and the claims of the present application for invention, are not intended to indicate any sequence, amount or importance, but distinguish various components. The phrases “connect”, “connected”, etc., are not intended to define a physical connection or mechanical connection, but may include an electrical connection, directly or indirectly “On,” “under,” “left,” “right” or the like is only used to describe a relative positional relationship, and when the absolute position of a described object is changed, the relative positional relationship might also be changed accordingly.

It should be appreciated that, in the case that such an element as layer, film, region or substrate is arranged “on” or “under” another element, it may be directly arranged “on” or “under” the other element, or an intermediate element may be arranged therebetween.

In descriptions of the implementation modes, the specific features, structures, materials, or characteristics described may be combined in any suitable manner in any one or more embodiments or examples.

The foregoing are only specific embodiments of the present disclosure, but the protection scope of the present disclosure is not limited thereto. In the technical scope disclosed by the present disclosure, changes or substitutions easily thought by any skilled in the art are all covered in the protection scope of the present disclosure. Therefore, the protection scope of the present disclosure should be the protection scope of the claims.

1. A display substrate, comprising a substrate, the substrate comprises a display area and a border area located around the display area, the border area comprises a sealing area; the display substrate further comprises:
a plurality of sub-pixels, located in the display area;
a plurality of power supply portions, located at least in the display area and electrically connected to the plurality of sub-pixels; and
a first power line, comprising a first power portion, a second power portion, and a plurality of power connection portions, the first power portion is located between the second power portion and the display area, and at least a portion of the second power portion is located between the display area and the sealing area, the first power portion is coupled to the plurality of power supply portions, the plurality of power connection portions are located between the first power portion and the second power portion, and are coupled to both the first power portion and the second power portion;
a multiplexer circuit, wherein at least a portion of an orthographic projection of the multiplexer circuit on the substrate is located between an orthographic projection of the first power portion on the substrate and an orthographic projection of the second power portion on the substrate;
the multiplexer circuit comprises a plurality of multiplexer units, the plurality of multiplexer units are alternately arranged with the plurality of power connection portions.

2. The display substrate according to claim 1, wherein the plurality of power connection portions comprise a first power connection portion and a plurality of second power connection portions, the plurality of second power connection portions comprise two sets of connection portion groups, an orthographic projection of the first power connection portion on the substrate is located between orthographic projections of the two sets of connection portion groups on the substrate;
a width of the first power connection portion in a direction perpendicular to its own extension direction is greater than a width of the second power connection portion in a direction perpendicular to its own extension direction.

3. The display substrate according to claim 1, wherein a width d3 of the second power portion in a direction perpendicular to its own extension direction satisfies: 15 μm≤d3≤25 μm.

4. The display substrate according to claim 1, wherein the display substrate comprises a first gate metal layer, a second gate metal layer, a first source drain metal layer, and a second source drain metal layer stacked in sequence along a direction away from the substrate; the power connection portion is arranged on the same layer as at least one of the first gate metal layer, the second gate metal layer, the first source drain metal layer, or the second source drain metal layer.

5. The display substrate according to claim 1, wherein the first power line further comprises at least one third power portion, the third power portion is coupled to the second power portion, and at least a portion of the third power portion is located in the sealing area;
the third power portion is arranged on the same layer as at least one of the first gate metal layer, the second gate metal layer, or the first source drain metal layer in the display substrate.

6. The display substrate according to claim 5, wherein the display substrate further comprises a first signal input terminal; the first power line comprises two third power portions, the two third power portions are symmetrically arranged; the first power line further comprises two fourth power portions, and the fourth power portion is coupled to a corresponding third power portion and the first signal input terminal.

7. The display substrate according to claim 6, wherein the first power line further comprises a fifth power portion and a sixth power portion, the fifth power portion is located between the two fourth power portions, and the fifth power portion is coupled to the two fourth power portions, at least a portion of the sixth power portion is located in the sealing area, and the sixth power portion is coupled to the fifth power portion and the second power portion.

8. The display substrate according to claim 1, wherein the display substrate further comprises a first signal input terminal; the first power line comprises a sixth power portion and a seventh power portion, the sixth power portion is coupled to the second power portion, and the seventh power portion comprises a first portion and two second portions, the first portion extends along a first direction, and the first portion is coupled to the sixth power portion and the two second portions, the second portion extends along a second direction, and the second portion is coupled to the first signal input terminal, the first direction intersects with the second direction.

9. The display substrate according to claim 1, wherein the display substrate further comprises:
a second power line, comprising an eighth power portion and two ninth power portions, the eighth power portion is arranged around the display area, and the two ninth power portions are coupled to two terminals of the eighth power portion in a one-to-one correspondence;
a second signal input terminal, coupled to the ninth power portion.

10. The display substrate according to claim 9, wherein the display substrate comprises a first gate metal layer, a second gate metal layer, a first source drain metal layer, and a second source drain metal layer stacked in sequence along a direction away from the substrate;
at least a portion of the ninth power portion is located in the sealing area, and the ninth power portion is arranged on the same layer as the first source drain metal layer in the display substrate.

11. The display substrate according to claim 9, wherein the display substrate comprises a first gate metal layer, a second gate metal layer, a first source drain metal layer, and a second source drain metal layer stacked in sequence along a direction away from the substrate;
at least a portion of the eighth power portion is located in the sealing area, and at least a portion of the eighth power portion is arranged on the same layer as the first gate metal layer in the display substrate.

12. The display substrate according to claim 11, wherein the display substrate further comprises a fan-out line, at least a portion of an orthographic projection of the fan-out line on the substrate is located between an orthographic projection of the eighth power portion on the substrate and the display area.

13. The display substrate according to claim 9, wherein the display substrate comprises a first gate metal layer, a second gate metal layer, a first source drain metal layer, and a second source drain metal layer stacked in sequence along a direction away from the substrate;
the ninth power portion comprises a third portion and a fourth portion coupled to each other, at least a portion of the third portion is located in the sealing area, and the fourth portion is located in an area outside the sealing area, the third portion is arranged on the same layer as the first gate metal layer in the display substrate, the third portion and the eighth power portion are integrated structures, and the fourth portion is arranged on the same layer as the first source drain metal layer in the display substrate.

14. The display substrate according to claim 9, wherein the display substrate further comprises a fan-out line; the eighth power portion comprises a fifth portion and a sixth portion, an orthographic projection of the fifth portion on the substrate is located between an orthographic projection of the sixth portion on the substrate and the display area; the fifth portion and the sixth portion are respectively coupled to the ninth power portion;
at least a portion of an orthographic projection of the fan-out line on the substrate is located between the orthographic projection of the fifth portion on the substrate and the orthographic projection of the sixth portion on the substrate.

15. The display substrate according to claim 1, wherein the display substrate further comprises a plurality of fan-out lines, at least some of the plurality of fan-out lines comprise a fan-out compensation portion, and at least a portion of the fan-out compensation portion located in the sealing area.

16. The display substrate according to claim 15, wherein the display substrate further comprises a sealing compensation portion, the sealing compensation portion is located in the sealing area, in the sealing area, a layout density of the sealing compensation portion is the same as a layout density of the fan-out line.

17. The display substrate according to claim 1, wherein the display substrate further comprises a plurality of fan-out lines, at least some of the plurality of fan-out lines comprise a fan-out compensation portion, the length of the fan-out compensation portions comprised in each fan-out line is approximately the same, and the fan-out compensation portions are uniformly arranged in the sealing area.

18. A display substrate, comprising a substrate, the substrate comprises a display area and a border area located around the display area, the border area comprises a sealing area; the display substrate further comprises:
a plurality of sub-pixels, located in the display area;
a plurality of power supply portions, located at least in the display area and electrically connected to the plurality of sub-pixels;
a first power line, comprising a first power portion, a second power portion, and a plurality of power connection portions, the first power portion is located between the second power portion and the display area, and at least a portion of the second power portion is located between the display area and the sealing area, the first power portion is coupled to the plurality of power supply portions, the plurality of power connection portions are located between the first power portion and the second power portion, and are coupled to both the first power portion and the second power portion; the first power line further comprises two third power portions and a sixth power portion, both of the third power portion and the sixth power portion are coupled to the second power portion, an orthographic projection of the sixth power portion on the substrate is located between orthographic projections of two third power portions on the substrate; and
a plurality of fan-out lines, at least some of the plurality of fan-out lines comprise a fan-out portion extending along a second direction, at least a portion of an orthographic projection of the fan-out portion on the substrate, is located between an orthographic projection of the third power portion on the substrate and the orthographic projection of the sixth power portion on the substrate.

19. The display substrate according to claim 18, wherein further comprising a multiplexer circuit, at least a portion of an orthographic projection of the multiplexer circuit on the substrate is located within an area enclosed by the first power portion, the second power portion, and the plurality of power connection portions.

20. A display device, comprising the display substrate according to claim 1.
